(19) United States
(12) Patent Application Publication
(10) Pub. No.: US 2025/0006498 A1
(43) Pub. Date: Jan. 2, 2025

(54) LASER IRRADIATION APPARATUS, LASER IRRADIATION METHOD, AND METHOD FOR MANUFACTURING SEMICONDUCTOR DEVICE

(71) Applicant: JSW Aktina System Co., Ltd., Yokohama-shi, Kanagawa (JP)

(72) Inventors: Ryosuke SATO, Yokohama-shi, Kanagawa (JP); Naoyuki KOBAYASHI, Yokohama-shi, Kanagawa (JP)

(73) Assignee: JSW Aktina System Co., Ltd., Yokohama-shi, Kanagawa (JP)

(21) Appl. No.: 18/708,320

(22) PCT Filed: Nov. 24, 2021
(86) PCT No.: PCT/JP2021/042893

§ 371 Date: May 8, 2024

(51) Int. Cl. H01L 21/268; H01L 21/67

(52) U.S. Cl. CPC H01L 21/268; H01L 21/67115

(57) ABSTRACT

A laser irradiation apparatus (1) according to an embodiment is a laser irradiation apparatus configured to activate a semiconductor layer of a semiconductor device, including: a semiconductor laser light source (35) configured to generate laser light (15) having a wavelength no shorter than 250 nm and no longer than 500 nm; an optical system unit (30) configured to guide the laser light to a semiconductor substrate; and a driving mechanism configured to change a relative irradiation place of the laser light in the semiconductor substrate.

### TECHNICAL FIELD

The present invention relates to a laser irradiation apparatus, a laser irradiation method, and a method for manufacturing a semiconductor device.

### BACKGROUND ART

Patent Literature 1 discloses a laser annealing apparatus using an excimer laser. In Patent Literature 1, a conveyance unit conveys a substrate in a state where the substrate is levitated by a levitation unit. Further, line-shaped laser light is applied to the substrate during the conveyance thereof.

### CITATION LIST

### Patent Literature

Patent Literature 1: Japanese Unexamined Patent Application Publication No. 2018-64048

### SUMMARY OF INVENTION

### Technical Problem

Since such an excimer laser light source is expensive, it is difficult to reduce the component cost of the apparatus. Therefore, it is desired to use a light source other than the excimer laser light source. A semiconductor laser is inexpensive, but it is a continuous wave (CW: Continuous Wave) laser. When CW laser light is modulated into pulsed laser light by a modulator, the output power is lowered. Therefore, a large number of light sources are required, making it difficult to reduce the cost.

Other problems to be solved and novel features will become apparent from descriptions in this specification and accompanying drawings.

According to an embodiment, a laser irradiation apparatus is one that is configured to activate a semiconductor layer of a semiconductor device, including: a semiconductor laser light source configured to generate laser light having a wavelength no shorter than 250 nm and no longer than 500 nm; an optical system unit configured to guide the laser light to a semiconductor substrate; and a driving mechanism configured to change a relative irradiation place of the laser light in the semiconductor substrate.

According to another embodiment, a laser irradiation apparatus is one that is configured to apply laser light to a semiconductor substrate in which a plurality of chip areas are formed, including: a laser light source configured to generate laser light; an optical system unit configured to guide the laser light to the semiconductor substrate so that a longitudinal size of a spot shape of the laser light in the semiconductor substrate is larger than a size of the chip area; and a driving mechanism configured to change a relative irradiation place of the laser light in the semiconductor substrate.

According to another embodiment, a laser irradiation method is one for activating a semiconductor layer of a semiconductor device, including the steps of: (A1) generating laser light having a wavelength no shorter than 250 nm and no longer than 500 nm; (A2) guiding the laser light to a semiconductor substrate by an optical system unit; and (A3) changing a relative irradiation place of the laser light in the semiconductor substrate.

According to another embodiment, a laser irradiation method is one for applying laser light to a semiconductor substrate in which a plurality of chip areas are formed, including the steps of: (B1) generating laser light; (B2) guiding the laser light to the semiconductor substrate so that a longitudinal size of a spot shape of the laser light in the semiconductor substrate is larger than a size of the chip area; and (B3) changing a relative irradiation place of the laser light in the semiconductor substrate.

According to another embodiment, a manufacturing method includes (S1) an irradiation step of applying laser light to a semiconductor substrate in order to activate a semiconductor layer of a semiconductor device, in which the (S1) irradiation step includes the steps of: (SA1) generating laser light having a wavelength no shorter than 250 nm and no longer than 500 nm; (SA2) guiding the laser light to the semiconductor substrate by an optical system unit; and (SA3) changing a relative irradiation place of the laser light in the semiconductor substrate.

According to another embodiment, a manufacturing method includes (T1) an irradiation step of applying laser light to a semiconductor substrate in which a plurality of chip areas are formed, in which the (T1) irradiation step includes the steps of: (TB1) generating laser light; (TB2) guiding the laser light to the semiconductor substrate so that a longitudinal size of a spot shape of the laser light in the semiconductor substrate is larger than a size of the chip area; and (TB3) changing a relative irradiation place of the laser light in the semiconductor substrate.

According to the embodiment, it is possible to provide a highly productive laser irradiation apparatus, a laser irradiation method, and a method for manufacturing a semiconductor device.

### BRIEF DESCRIPTION OF DRAWINGS

FIG. 1 is a plan view schematically showing a laser irradiation apparatus according to a first embodiment;

FIG. 2 is an XZ cross-sectional view schematically showing the laser irradiation apparatus according to the first embodiment;

FIG. 3 is a YZ cross-sectional view schematically showing the laser irradiation apparatus according to the first embodiment;

FIG. 4 is a plan view for explaining a spot shape of an object to be processed;

FIG. 5 is a plan view for explaining a spot shape of an object to be processed;

FIG. 6 is an XZ cross-sectional view schematically showing a laser irradiation apparatus according to a second embodiment;

FIG. 7 is a YZ cross-sectional view schematically showing the laser irradiation apparatus according to the second embodiment;

FIG. 8 is a plan view for explaining a spot shape of an object to be processed;

FIG. 9 is a graph showing profiles of impurity concentrations after laser irradiation is performed; and

FIG. 10 is a cross-sectional view showing an example of a structure of a semiconductor device manufactured by a manufacturing method according to an embodiment.

### DESCRIPTION OF EMBODIMENTS

### First Embodiment

A laser irradiation apparatus according to this embodiment performs an annealing process on an object to be processed (also referred to as a workpiece) by applying laser light to the object to be processed. The laser irradiation apparatus performs an activation process on a semiconductor layer provided in a substrate by heating the substrate by the laser light. The object to be processed is a semiconductor substrate for forming semiconductor chips. The semiconductor substrate is a silicon wafer or a compound semiconductor wafer.

For example, a power semiconductor device such as a vertical MOSFET (Metal-Oxide-Semiconductor Field-Effect Transistor) or an IGBT (Insulated Gate Bipolar Transistor) is formed over a semiconductor substrate. That is, the object to be processed is a semiconductor wafer in which chips of power semiconductor devices are formed. The semiconductor substrate includes a semiconductor layer doped with impurities (which is also referred to as an impurity-doped layer). A laser irradiation apparatus can activate such a semiconductor layer by applying laser light thereto. Further, a method according to this embodiment is not limited to methods for power semiconductors. For example, a method according to this embodiment can be applied to the activation of a semiconductor layer of a semiconductor chip such as an image sensor and its manufacturing method.

The laser irradiation apparatus uses a blue semiconductor laser light source as a laser light source. The laser irradiation apparatus applies blue laser light to an object to be processed from the semiconductor laser light source, and thereby performs an annealing process for activating the object to be processed. Note that the laser light is not limited to the blue laser light, but can be any laser light having a wavelength no shorter than 250 nm and no longer than 500 nm.

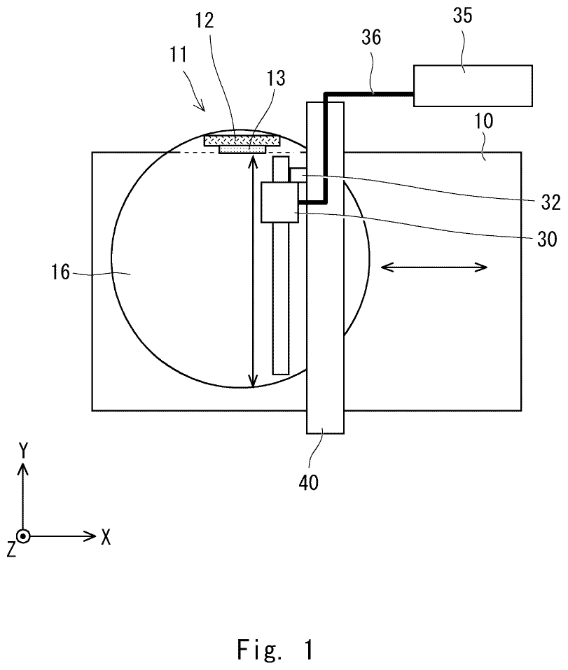

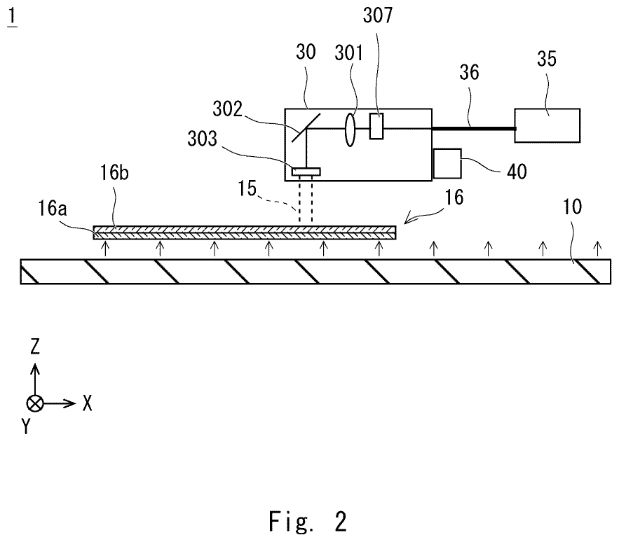

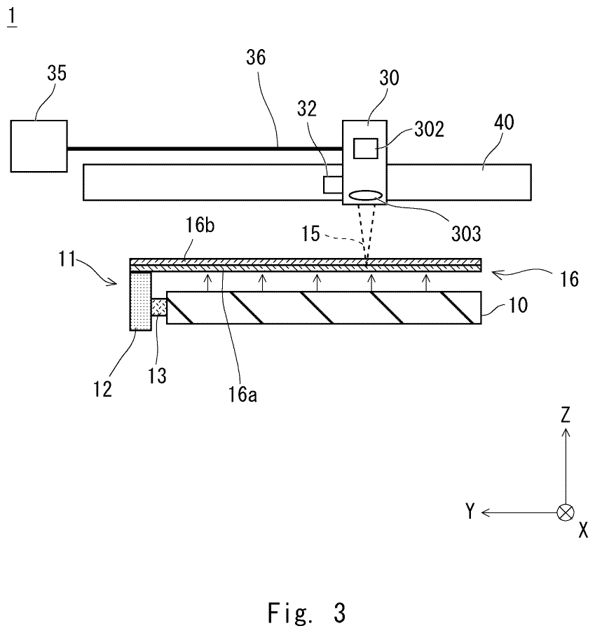

A configuration of a laser irradiation apparatus according to this embodiment will be described with reference to FIGS. 1 to 3. FIG. 1 is a plan view schematically showing the configuration of the laser irradiation apparatus 1. FIG. 2 is an XZ cross-sectional view schematically showing the configuration of the laser irradiation apparatus 1. FIG. 3 is a YZ cross-sectional view schematically showing the configuration of the laser irradiation apparatus 1.

As shown in FIGS. 1 to 3, the laser irradiation apparatus 1 includes a levitation unit 10, a conveyance unit 11, an optical system unit 30, a Y-driving mechanism 32, and a stage 40. The levitation unit and the conveyance unit 11 constitute a conveyance apparatus.

Note that in the drawings described below, an XYZ three-dimensional orthogonal coordinate system is shown as appropriate to simplify the description. The Z direction is a vertical direction and is a direction perpendicular to the main surface of the object to be processed 16. The X direction is a direction in which the object to be processed 16 is conveyed. The Y direction is a direction in which the optical system unit 30 moves. Laser light 15 is applied to the object to be processed 16, which is being conveyed in the X direction. Further, the optical system unit 30 moves in the Y direction. Therefore, it is possible to change the irradiation place of the laser light in the object to be processed 16 in the X and Y directions. In this way, it is possible to irradiate substantially the entire surface of the object to be processed 16 with laser light.

As shown in FIG. 2, the levitation unit 10 is configured to eject a gas from its surface. The levitation unit 10 levitates, i.e., floats, the object to be processed 16 over its top surface. The object to be processed 16 is levitated as the gas ejected from the surface of the levitation unit 10 is blown onto the bottom surface of the object to be processed 16. When the object to be processed 16 is conveyed, the levitation unit 10 adjusts the levitation height of the object to be processed 16 so that it does not come into contact with other mechanisms (not shown) disposed above the object to be processed 16.

The levitation unit 10 is formed of a porous material. For example, the levitation unit 10 is formed of a ceramic material such as porous alumina or porous SiC. Note that the levitation unit 10 is composed of a plate made of a porous material and having a thickness of 10 mm. The levitation unit 10 is connected to an air supply port (not shown). Therefore, a gas from gas supply means such as a gas cylinder (not shown) is ejected from the upper surface of the levitation unit 10.

The conveyance unit 11 conveys the levitated object to be processed 16 in the conveyance direction. As shown in FIG. 1, the conveyance unit 11 includes a holding mechanism 12 and a moving mechanism 13. The holding mechanism 12 holds the object to be processed 16. For example, the holding mechanism 12 can be formed by using a vacuum absorption mechanism. The vacuum absorption mechanism is formed by a metal material such as an aluminum alloy. Alternatively, the holding mechanism 12 can be formed of a resin-based material such as a PEEK (polyether ether ketone) material. Absorption grooves, absorption holes, or the like are formed in the top surface of the holding mechanism 12. The holding mechanism 12 may be formed of a porous material.

The holding mechanism 12 (the vacuum absorption mechanism) is connected to an exhaust port (not shown) and the exhaust port is connected to an ejector, a vacuum pump, or the like. Therefore, since a negative pressure for adsorbing a gas acts on the holding mechanism 12, the object to be processed 16 can be held by using the holding mechanism 12.

The holding mechanism 12 holds the object to be processed 16 by adsorbing the surface (the bottom surface) of the object to be processed 16 opposite to the surface (the top surface) thereof to which laser light 15 is applied, i.e., by adsorbing the surface of the object to be processed 16 that is opposed to the levitation unit 10. Further, the holding mechanism 12 holds the end of the object to be processed 16 in the ty direction (i.e., the end of the object to be processed 16 on the positive side in the y direction).

The moving mechanism 13 included in the conveyance unit 11 is connected to the holding mechanism 12. The moving mechanism 13 is configured to be able to move the holding mechanism 12 in the conveyance direction. The conveyance unit 11 (the holding mechanism 12 and the moving mechanism 13) is disposed at an end of the levitation unit 10 in the +y direction. Further, the object to be processed 16 is conveyed as the moving mechanism 13 moves in the conveyance direction while the holding mechanism 12 is holding the object to be processed 16.

As shown in FIG. 1, for example, the moving mechanism 13 is configured to slide in the conveyance direction at the end of the levitation unit 10 in the ty direction. As the moving mechanism 13 slides in the conveyance direction at the end of the levitation unit 10, the object to be processed 16 is conveyed along the conveyance direction.

Note that the conveyance speed of the object to be processed 16 can be controlled by controlling the moving speed of the moving mechanism 13. The moving mechanism 13 includes, for example, an actuator such as a motor, a liner guide mechanism, an air bearing, etc. (not shown).

The object to be processed 16 is a substantially circular semiconductor wafer. Note that orientation-flat, a notch(es), and the like may be formed in the semiconductor wafer. The object to be processed 16 includes a substrate 16a and a semiconductor layer 16b formed above the substrate 16a. The substrate 16a is a semiconductor substrate such as a silicon wafer or a compound semiconductor wafer (SiC, GaN). Needless to say, the material of the substrate 16a is not limited to any particular materials. The substrate 16a is opaque to light having the laser wavelength.

The semiconductor layer 16b is an impurity-doped layer doped with impurities such as phosphorus (P) or boron (B). It is possible to activate PN junctions in the semiconductor layer 16b by applying laser light 15 to the semiconductor layer 16b and thereby performing an annealing process. That is, the laser irradiation apparatus 1 is an annealing apparatus for activating the semiconductor layer 16b. Note that although only the semiconductor layer 16b is shown in the drawing, other films or layers may be formed. For example, a thin film made of copper or aluminum, which forms wiring lines and the like, may be formed. Further, an insulating layer such as a silicon oxide film may be formed in the substrate 16a.

The stage 40 is disposed above the levitation unit 10. The stage movably holds the optical system unit 30. The optical system unit guides laser light emitted from a laser light source 35 to the object to be processed 16. The optical system unit 30 is disposed on the −X side of the stage 40. Therefore, the optical system unit 30 is positioned right above the object to be processed 16. Therefore, the laser light 15 emitted from the optical system unit 30 is applied to the object to be processed 16 from above it.

The stage 40 serves as a guide mechanism for guiding the movement of the optical system unit 30 in the Y direction. For example, the stage 40 includes a guide rail(s), a guide groove(s), or the like. Further, the Y-driving mechanism 32 is provided in the stage 40. The stage 40 is a gantry stage that is provided in a space above the levitation unit 10 and extends along the Y-direction. The Y-driving mechanism 32 drives the optical system unit 30 in the Y-direction.

The optical system unit 30 moves along the stage 40. Since the optical system unit 30 moves in the Y direction, the irradiation place of the laser light 15 changes in the Y direction. The stage 40 is disposed so as to protrude from the levitation unit 10 on the +Y and −Y sides. Therefore, in the Y direction, the optical system unit 30 can apply laser light to any place of the object to be processed 16.

Next, an example of the laser light source and its optical system will be described. The laser light source 35 generates laser light for annealing an object to be processed 16. The laser light source 35 is a BLD(s) (Blue Laser Diode(s)) that generates blue laser light having a center wavelength of 450 nm. That is, the laser light source 35 is a blue semiconductor laser light source. Note that the laser light is continuously oscillating-type CW (Continuous Wave) laser light. Needless to say, the laser irradiation apparatus 1 may modulate laser light into pulsed laser light by using a modulator or the like.

The laser light source 35 is coupled to an optical fiber 36. Laser light emitted from the laser light source 35 enters the optical system unit 30 through the optical fiber 36. As shown in FIG. 2, the optical system unit 30 includes a lens 301, a mirror 302, a lens 303, and a beam shaping part 307. Needless to say, the optical system unit may include optical elements other than the lens 301, the mirror 302, the lens 303, and the beam shaping part 307.

The laser light exiting from the optical fiber 36 enters the beam shaping part 307. The beam shaping part 307 shapes a spot shape of the laser light. For example, the beam shaping part 307 includes a beam shaping mechanism such as a slit. Alternatively, in the case where a plurality of optical fibers 36 are used, the beam may be shaped by positioning the exiting end of the optical fiber 36. The beam shaping part 307 shapes the beam so that the cross-sectional shape (spot shape) of the beam in the direction perpendicular to the optical axis becomes rectangular. For example, the spot shape is a rectangular shape having a size of 10 to 14 mm in the longitudinal direction and a size of 0.5 mm in the lateral direction. It is possible to make the distribution of intensity of the laser light a top-flat distribution by using a beam homogenizer or the like in the beam shaping part 307. Note that the spot shape of the beam in the object to be processed 16 will be described later.

The laser light shaped by the beam shaping part 307 enters the lens 301. The laser light concentrated by the lens 301 is incident on the mirror 302. The mirror 302 reflects the laser light toward the object to be processed 16. Specifically, the mirror 302 reflects the laser light downward. The laser light reflected by the mirror 302 enters the lens 303.

The laser light 15 exiting from the lens 303 is applied to the object to be processed 16. The lens 303 concentrates the laser light 15 in the object to be processed 16. Therefore, the laser light 15 exiting from the optical system unit 30 becomes a converged beam and is applied to the object to be processed 16. The lens 303 may be a cylindrical lens. In this way, it is possible to convert the laser light into a line beam which has a line-like shape in the object to be processed 16.

The optical system unit 30 applies laser light 15 to the object to be processed 16 from above it. The semiconductor layer 16b of the object to be processed 16 is annealed, so that an activation process can be performed on the semiconductor layer 16b.

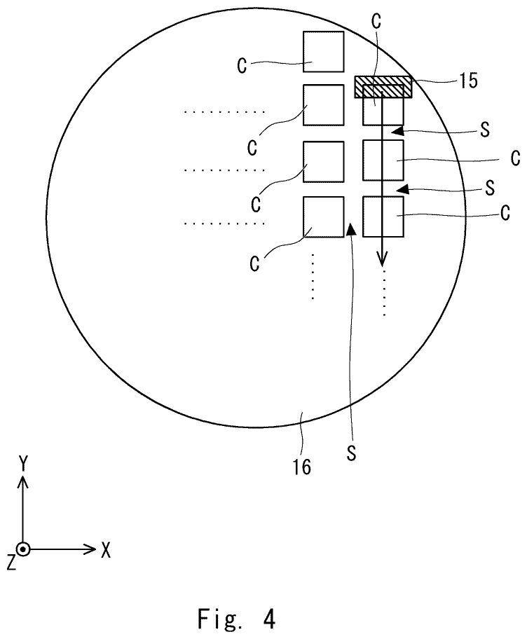

The spot shape in the object to be processed 16 will be described with reference to FIG. 4. FIG. 4 is a plan view schematically showing the object to be processed 16 and the spot shape of the laser light 15. A plurality of chip areas C are formed in the object to be processed 16. A power semiconductor chip is formed in each of the chip areas C. The chip areas C are arranged in a matrix pattern along the X and Y directions. In the plan view, each chip area C is rectangular. The chip area C (i.e., each of the chip areas) is an area where a semiconductor circuit is formed.

The area between two chip areas C adjacent to each other serves as a scribe line S. A semiconductor wafer is cut along the scribe line S, so that semiconductor chips are cut out therefrom. Note that each scribe line S between chip areas C is parallel to the X or Y direction. That is, scribe lines S are formed in a lattice pattern. The semiconductor wafer is cut in the X and Y directions, so that semiconductor chips are formed.

Note that the spot shape of the laser light 15 is formed in a line-like shape of which the longitudinal direction is parallel to the X direction and the lateral direction is parallel to the Y direction. That is, the laser light 15 is a line beam extending in the X direction over the object to be processed 16. For example, the laser light 15 is rectangular, and its spot size is 14 mm in the X direction and 0.5 mm in the Y direction. Further, the laser light 15 is CW light having output power of 2 kW.

The size of the spot shape of the laser light 15 in the longitudinal direction (X direction) is larger than the size of the chip area C. The beam shaping part 307 of the optical system unit 30 shapes the laser light so that the size of the laser light in the longitudinal direction is larger than the size of the chip area C over the object to be processed 16. The end part of the spot shape of the laser light 15 on the +X side is disposed on the +X side of the chip area C, and the end part thereof on the −X side is disposed on the −X side of the chip area C. That is, the end parts of the laser spot are positioned over the scribe lines S. Therefore, when the Y-driving mechanism 32 moves the optical system unit 30 in the Y-direction, the whole chip areas C in one row are irradiated with the laser light. That is, by moving the optical system unit 30 in the Y-direction, it is possible to scan (i.e., irradiate) the whole chip areas C in one row with the laser light 15.

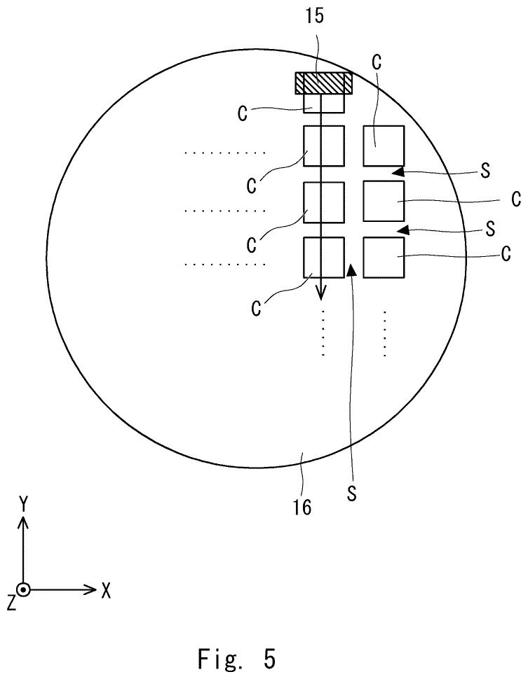

Further, the conveyance unit 11 moves the object to be processed 16 in the X direction. As a result, the irradiation place of the laser light 15 changes in the X direction. For example, when the conveyance unit 11 moves the object to be processed 16 from the state shown in FIG. 4 by a distance equivalent to one row in the X direction, the position of the laser light 15 is changed to the position shown in FIG. 5. Then, when the Y-driving mechanism 32 moves the optical system unit 30 in the Y-direction, the laser light is applied to the chip areas C in the second row. By repeating the above-described process, the whole chip areas C is irradiated with the laser light.

Note that although the directions in which the chip areas C are scanned in the first and second rows are the same as each other in FIG. 5, they may be opposite to each other. For example, when the irradiation place of the laser light is moved in the −Y direction in the chip areas C in the first row, the irradiation place of the laser light may be moved in the +Y direction in the chip areas C in the second row.

As described above, the irradiation place of the laser light 15 in the object to be processed 16 changes in the X and Y directions. Therefore, the raster scanning or zigzag scanning with the laser light 15 can be performed. It is possible to irradiate substantially the entire surface of the object to be processed 16 with the laser light 15.

The distribution of intensity of the laser light in the irradiation spot of the laser light 15 is a top-flat distribution or a Gaussian distribution. For example, by making the distribution of intensity of the laser light a top-flat distribution, it is possible to apply laser light with uniform intensity over the chip areas C. In this way, it is possible to appropriately activate the semiconductor layer, and thereby to improve the productivity.

The beam shaping part 307 shapes the beam so that the distribution of intensity becomes a top-flat distribution. For example, the distribution of intensity of the laser light is preferably a top-flat distribution in one arbitrary direction in the object to be processed 16. More preferably, the distribution of intensity of the laser light is a top-flat distribution in the X and Y directions.

The optical system unit 30 moves in the lateral direction of the laser light 15 in the object to be processed 16. That is, during the movement of the optical system unit 30 in the Y direction, CW laser light of which the lateral direction is parallel to the Y direction is applied to the object to be processed 16. Therefore, it is possible to reduce the irradiation time (heating time) during which the laser light is continuously applied to one point of the object to be processed 16. The moving speed of the optical system unit 30 in the Y direction is, for example, 1 m/sec. When the spot size in the Y direction is 0.5 mm, the heating time is 0.5 msec. In this way, it is possible to prevent any part of an underlying film or the like from being locally heated. As a result, it is possible to perform a stable annealing process and thereby to improve the productivity.

By setting the moving speed according to the spot shape of the laser light in the object to be processed 16, the irradiation time for each place can be adjusted. The irradiation time for each place in the object to be processed 16 is preferably 100 usec or shorter. That is, the moving speed of the optical system unit 30 is set so that the irradiation time for each place in the object to be processed 16 becomes 100 usec or shorter. In this way, it is possible to prevent any part of the object to be processed 16 from being locally heated, and there to anneal it appropriately.

Further, the laser light is applied so that the end parts of the irradiation spot thereof in the X direction are positioned over the scribe lines S. That is, the laser light is applied so that the edge positions of the irradiation spot do not coincide with the chip areas C in the X direction. In this way, it is possible to reduce the unevenness of the intensity of the irradiation in the X direction in one chip area C. Therefore, it is possible to irradiate the whole chip areas in the X direction with laser light having uniform intensity. As a result, the productivity can be improved.

Note that although the laser light has such a spot size in the X direction that the whole chip areas in one row can be irradiated with the laser light in the above description, it may have such a size that the whole chip areas C in two rows or more can be irradiated with the laser light at a time. That is, the spot size of the laser light in the X direction may be larger than twice the size of the chip area C. Even in this case, the edge positions of the irradiation spot of the laser light in the X direction are preferably positioned over the scribe lines S.

Further, in this embodiment, the laser light source 35 generates laser light having a wavelength no shorter than 250 nm and no longer than 500 nm. By using laser light having a center wavelength between 250 nm and 500 nm, a semiconductor layer can be appropriately activated. By using laser light having a deep penetration depth into the semiconductor layer 16b, a semiconductor layer can be activated to a deeper area thereof. Further, since a continuously oscillating-type semiconductor laser light source can be used in this wavelength range, the configuration of the apparatus can be simplified and the cost thereof can be reduced.

For example, laser light having a wavelength of 450 nm has a penetration depth of 0.24 μm into a silicon film. Therefore, it is possible to reduce the absorption of the laser light in the semiconductor layer 16b, so that the laser light reaches a deep area of the semiconductor layer 16b. Accordingly, it is suitable for manufacturing of a semiconductor device in which PN junctions are generated in a deep area. For example, the laser irradiation apparatus 1 is suitable for activating a power semiconductor device such as a vertical MOSFET and an IGBT. The laser irradiation apparatus 1 is suitable for a process for activating a semiconductor device in which PN junctions are formed in a deep area of a semiconductor substrate. It is possible to manufacture semiconductor devices with high productivity.

Note that by using the levitation unit 10, it is possible to prevent the object to be processed 16 from being fixed at the irradiation place of the laser light. That is, the levitation unit 10 can hold the object to be processed 16 in such a manner that the object to be processed 16 is not fixed at the irradiation place of the laser light. In this way, it is possible to relax the stress generated in the object to be processed 16 due to local thermal expansion or the like.

### Second Embodiment

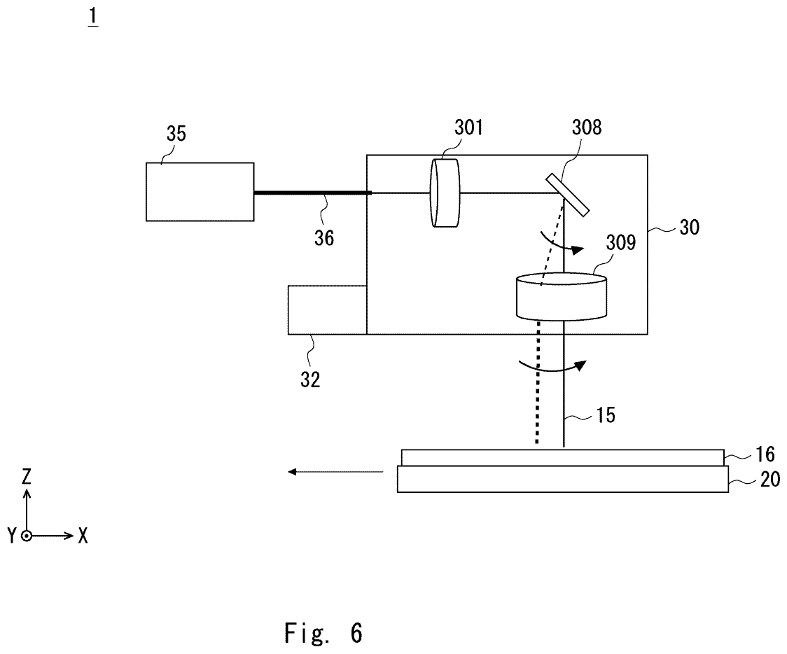

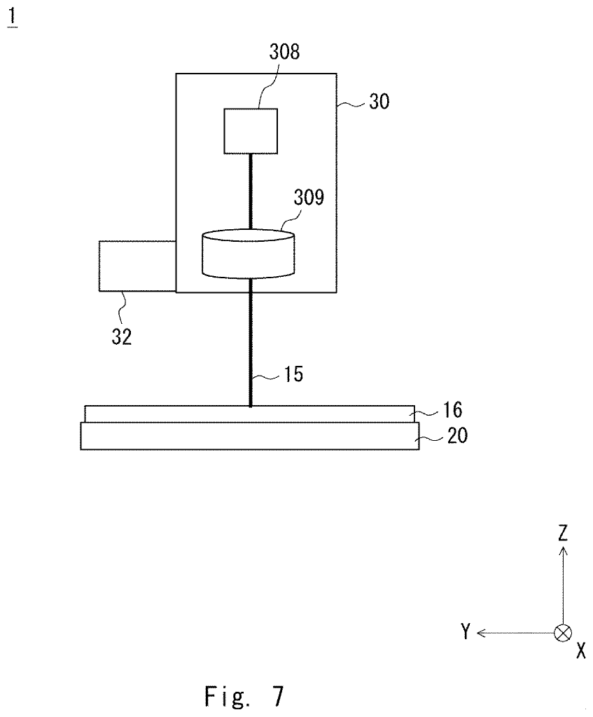

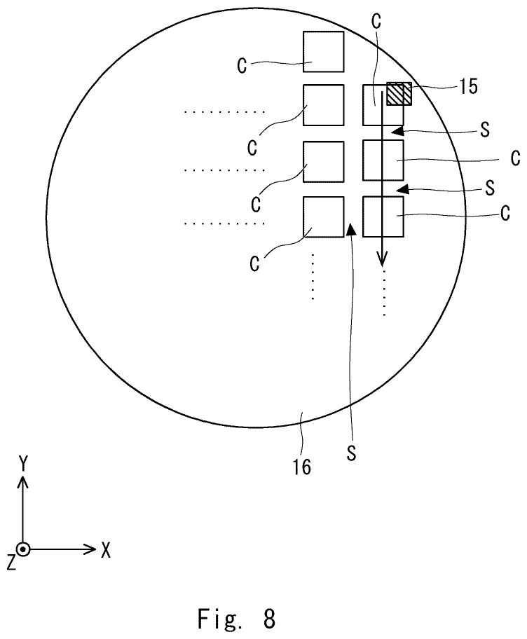

A laser irradiation apparatus according to a second embodiment will be described with reference to FIGS. 6 to 8. FIG. 6 is an XZ plan view showing a configuration of a laser irradiation apparatus 1. FIG. 7 is a YZ plan view showing the configuration of the laser irradiation apparatus 1. FIG. 8 shows an object to be processed 16 and a spot shape of laser light 15. Note that since the basic configuration of the laser irradiation apparatus 1 is similar to that of the first embodiment, the description thereof will be omitted and the drawing will be simplified. For example, similarly to the first embodiment, a light source is a laser light source having a wavelength no shorter than 250 nm and no longer than 500 nm.

In this embodiment, the object to be processed 16 is placed above a drive stage 20. The drive stage 20 holds the object to be processed 16 movably in the XY direction. For example, the drive stage 20 includes a motor, a guide mechanism, and the like for moving the object to be processed 16 in the XY direction. As the drive stage moves, the object to be processed 16 placed above the drive stage is moved. Therefore, the irradiation place of the laser light 15 in the object to be processed 16 can be changed.

The drive stage 20 may be an adsorbing stage (or a sucking stage) that holds an object to be processed 16 by adsorbing (or sucking) it. For example, the drive stage 20 may be a vacuum chuck stage or an electrostatic chuck stage.

Laser light emitted from the laser light source 35 enters the optical system unit 30 through the optical fiber 36. The laser light exiting from the optical fiber enters a lens 301, an optical scanner 308, and an fθ lens 309 in this order. The lens 301 concentrates the laser light toward the optical scanner 308. The optical scanner 308 reflects the laser light toward the fθ lens 309.

The optical scanner 308 is, for example, a galvano-mirror or the like and deflects the laser light 15. Since the optical scanner 308 changes the deflection angle of the laser light 15, the irradiation place of the laser light 15 is changed over the object to be processed 16. Laser light L1 is scanned (i.e., moved) in the X direction.

Specifically, the optical scanner 308 is operated (i.e., driven) by a drive motor or the like that rotates about the Y-axis. The optical scanner 308 scans the laser light 15 along the X direction over the object to be processed 16. That is, when the optical scanner 308 scans the laser light 15, the irradiation place of the laser light 15 is moved in the X direction over the object to be processed 16. Note that the optical scanner 308 is not limited to galvano-mirrors, but may be a polygon mirror, an acoustooptic element, or the like.

The fθ lens 309 refracts the laser light 15 reflected by the optical scanner 308. By disposing the fθ lens 309 right above the object to be processed 16, it is possible to make the focal plane of the laser light 15 coincide with the main plane of the object to be processed 16. That is, the focal place of the laser light 15 is fixed at a certain height in the Z direction irrespective of the deflection angle of the optical scanner 308. In this way, it is possible to make the irradiation power density of the laser light 15 in the object to be processed 16 constant.

The spot shape of the laser light L1 applied to the object to be processed 16 may be circular or rectangular. The distribution of intensity of the laser light 15 in the cross section of the beam may be a Gaussian distribution. Alternatively, the distribution of intensity of the laser light 15 may have a top-flat shape (top-hat shape) by using a modulator or the like. When the laser light 15 needs to be applied more uniformly, the spot shape of the laser light L1 is preferably rectangular and the distribution of intensity thereof is preferably a top-flat distribution.

For example, the spot shape of the laser light in the object to be processed 16 is a square of 0.5 mm×0.5 mm. Further, the optical scanner 308 scans (i.e., moves) the laser light 15 in the X direction. Further, the Y-driving mechanism 32 drives the optical system unit 30 in the Y direction. As a result, it is possible to move the irradiation place of the laser light at a high speed in the X and Y directions.

The scanning speed of the optical scanner 308 is higher than the moving speed of the irradiation place of the laser light moved by the Y-driving mechanism 32 and the drive stage 20. By using the optical scanner 308, it is possible to reduce the irradiation time (heating time) at an arbitrary point of the object to be processed 16. It is possible to perform a stable process and thereby to improve the productivity.

By setting the scanning speed according to the spot shape of the laser light in the object to be processed 16, the irradiation time for each place can be adjusted. The irradiation time for each place in the object to be processed 16 is preferably 100 usec or shorter. That is, the scanning speed is set so that the irradiation time for each place in the object to be processed 16 becomes 100 usec or shorter. In this way, it is possible to prevent any part of the object to be processed 16 from being locally heated, and thereby to anneal it appropriately.

Assume that, for example, the direction in which the optical scanner 308 performs scanning is defined as an X direction, and the direction in which the optical system unit 30 moves is defined as a Y direction. Then, the moving the drive stage 20 moves can be set in the X direction. As a result, two-dimensional scanning can be performed, so that substantially the entire surface of the object to be processed 16 can be annealed. Needless to say, the scanning direction of the optical scanner 308, the moving direction of the optical system unit 30, and the moving direction of the drive stage 20 are not limited to any particular directions.

Note that although a blue laser diode(s) is provided as the laser light source 35 in each of the first and second embodiments, the laser light source 35 is not limited to this example. Specifically, the laser light source 35 preferably generates laser light having a wavelength no shorter than 250 nm and no longer than 500 nm. Needless to say, the laser light may have a wavelength outside the aforementioned range.

The drive stage 20 may hold the object to be processed 16 in such a manner that the object to be processed 16 is not fixed at the irradiation place of the laser light. For example, in the second embodiment, the drive stage 20 may be a non-adsorbing-type stage that does not hold the object to be processed 16 by absorbing it. When the drive stage 20 is an adsorbing-type stage, the drive stage 20 may be configured so as to be able to partially adsorb the object to be processed 16. For example, in the object to be processed 16, the adsorption area of the adsorbing stage may be divided into a plurality of sections, and the on/off of the adsorption is controlled in each section. By doing so, the drive stage 20 can adsorb the object to be processed 16 at a part other than the laser irradiation place without adsorbing it at the laser irradiation place. In this way, the drive stage can hold the object to be processed 16 in such a manner that the object to be processed 16 is not fixed at the laser irradiation place. By doing so, it is possible to relax the stress generated in the object to be processed 16 due to local thermal expansion or the like.

Note that the first and second embodiments can be used while combining them with each other as appropriate. For example, in the first embodiment, the levitation unit 10 and the conveyance unit 11 can be replaced by the drive stage 20. Alternatively, in the second embodiment, the drive stage 20 can be replaced by the levitation unit and the conveyance unit 11. Further, an optical scanner 304 can also be used in the first embodiment. As the means for changing the irradiation place of the laser light, at least one of the drive stage 20, the conveyance unit 11, the Y-driving mechanism 32 of the optical system unit, and the optical scanner 304 can be used.

### EXAMPLES

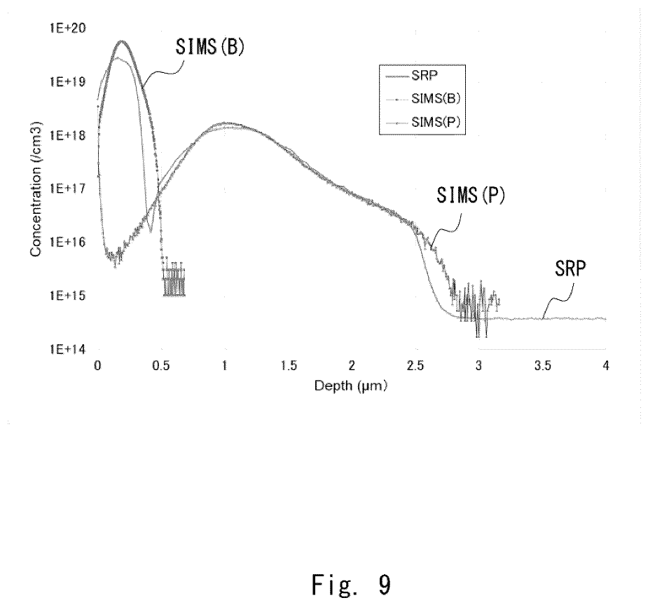

FIG. 9 is a graph showing profiles of impurity concentrations after laser irradiation is performed. Note that as the object to be processed 16, silicon wafers each having a thickness of 150 μm were doped with ions of boron (B) and phosphorus (P), respectively. FIG. 9 shows SIMS (Secondary Ion Mass Spectrometry) profiles of boron and phosphorus, respectively. Further, FIG. 9 shows profiles obtained by SRP (Spreading Resistance Profiling). In FIG. 9, the horizontal axis indicates the thickness and the vertical axis indicates the impurity concentration. Results that were obtained when a line beam was applied as described in the first embodiment are shown. Note that the beam size in the object to be processed 16 is 10 mm×0.5 mm.

The power density of the laser light 15 in the object to be processed 16 was 40 kW/cm2, and the laser power thereof was 2 kW. The energy density was 60 J/cm²; the irradiation time was 1.5 msec; and the moving speed of the optical system unit 30 was 333 mm/sec. The activation rate of boron was 61%, and that of phosphorus was 107%. Therefore, the impurity layer can be appropriately activated by the laser irradiation method according to this embodiment.

### (Semiconductor Device)

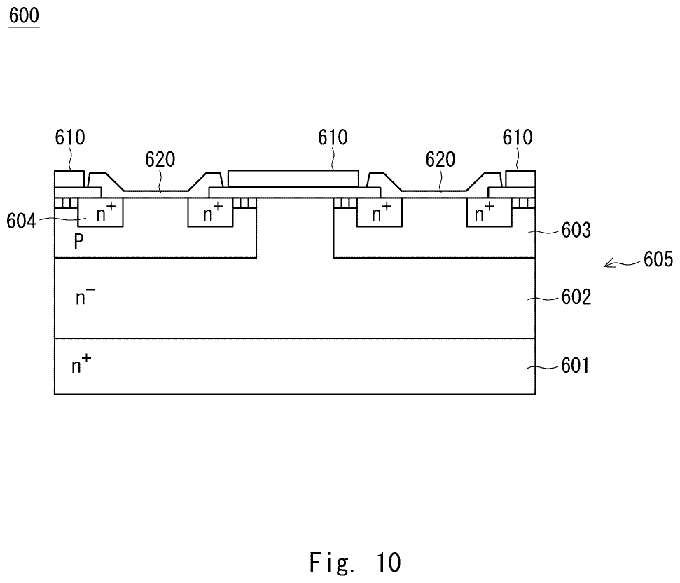

An example of a semiconductor device manufactured by a manufacturing method according to this embodiment will be described hereinafter. FIG. 10 is a cross-sectional view showing a stacking structure of a semiconductor device 600. The semiconductor device 600 is a vertical MOSFET. Specifically, the semiconductor device 600 is a planar-type MOSFET, in which the back side of a semiconductor substrate 605 serves as a drain, and the front side thereof serves as a source and a gate. The semiconductor substrate 605 is a silicon substrate.

In the semiconductor device 600, an n⁺ layer 601, an n⁻ layer 602, a player 603, and an n⁺ layer 604 are formed in this order from the backside of the semiconductor substrate 605. Further, a gate electrode 610 and a source electrode 620 are formed over the front surface of the semiconductor substrate 605. Each of the gate and source electrodes 610 and 620 is a thin metal film made of copper, aluminum, or the like. The semiconductor substrate 605 corresponds to the above-described object to be processed 16 or the substrate 16a.

Each of the n⁺ layer 601, the n⁻ layer 602, the p layer 603, and the n⁺ layer 604 is doped with impurities. For example, the p layer 603 is doped with boron as a dopant. The n⁺ layer 601, the n⁻ layer 602, and the n⁺ layer 604 are doped with phosphorus as a dopant. The n⁺ layer 601, the n⁻ layer 602, the p layer 603, or the n⁺ layer 604 correspond to the semiconductor layer 16b.

As the laser irradiation apparatus 1 applies laser light to the semiconductor substrate 605, at least one of the n⁺ layer 601, the n⁻ layer 602, the p layer 603, and the n⁺ layer 604 can be activated. The laser light 15 is applied to the semiconductor substrate 605 from the upper surface thereof. By doing so, the n⁺ layer 601, the n⁻ layer 602, the p layer 603, or the n⁺ layer 604 can be activated. Note that the order of the steps of applying laser light is not limited to any particular orders.

Further, a method according to this embodiment is an irradiation method for activating a semiconductor layer of a semiconductor device, including the steps of: generating laser light having a wavelength no shorter than 250 nm and no longer than 500 nm; guiding the laser light to a semiconductor substrate by an optical system unit; and changing a relative irradiation place of the laser light in the semiconductor substrate. By this method, the semiconductor layer can be appropriately activated. This laser irradiation method is suitable for a method for manufacturing a semiconductor device. That is, the laser irradiation method is applied to an activation step in a method for manufacturing a semiconductor device.

A laser irradiation method according to this embodiment is a laser irradiation method for applying laser light to a semiconductor substrate in which a plurality of chip areas are formed, including the steps of: generating laser light; guiding the laser light to the semiconductor substrate so that a longitudinal size of a spot shape of the laser light in the semiconductor substrate is larger than a size of the chip area; and (B3) changing a relative irradiation place of the laser light in the semiconductor substrate. By this method, laser light can be appropriately applied. This laser irradiation method is suitable for a method for manufacturing a semiconductor device. That is, the laser irradiation method is applied to an activation step in a method for manufacturing a semiconductor device.

The first and second embodiments can be used while combining a part or the whole of them with each other as appropriate. Note that the present invention is not limited to the above-described embodiments, and they can be modified as appropriate without departing from the scope and spirit of the invention.

### REFERENCE SIGNS LIST

1 LASER IRRADIATION APPARATUS
10 LEVITATION UNIT
11 CONVEYANCE UNIT
12 HOLDING MECHANISM
13 MOVING MECHANISM
15 LASER LIGHT
16 OBJECT TO BE PROCESSED
16a SUBSTRATE
16b SEMICONDUCTOR LAYER
20 DRIVE STAGE
30 OPTICAL SYSTEM UNIT
32 Y-DRIVING MECHANISM
301 LENS
302 MIRROR
303 LENS
40 STAGE

1. A laser irradiation apparatus configured to activate a semiconductor layer of a semiconductor device, comprising:
a laser light source configured to generate laser light having a wavelength no shorter than 250 nm and no longer than 500 nm;
an optical system unit configured to guide the laser light to a semiconductor substrate; and
a driving mechanism configured to change a relative irradiation place of the laser light in the semiconductor substrate.

2. The laser irradiation apparatus according to claim 1, wherein
a plurality of chip areas are provided in the semiconductor substrate, the plurality of chip areas being areas in each of which a semiconductor device is formed, and
the optical system unit shapes the laser light so that a longitudinal size of the laser light becomes larger than a size of the chip area in the semiconductor substrate.

3. The laser irradiation apparatus according to claim 2, further comprising an adsorbing stage configured to adsorb and hold the semiconductor substrate, wherein
the driving mechanism moves the adsorbing stage.

4. The laser irradiation apparatus according to claim 2, further comprising:
a levitation unit configured to levitate the semiconductor substrate;
a conveyance unit configured to convey the semiconductor substrate, which is being levitated above the levitation unit, in a first direction; and
a drive stage configured to hold the optical system unit, which is disposed above the levitation unit, movably in a second direction different from the longitudinal direction in a plan view.

5. The laser irradiation apparatus according to claim 1, wherein an optical scanner configured to scan the laser light is provided in the optical system unit.

6. A laser irradiation apparatus configured to apply laser light to a semiconductor substrate in which a plurality of chip areas are formed, comprising:
a laser light source configured to generate laser light;
an optical system unit configured to guide the laser light to the semiconductor substrate so that a longitudinal size of the laser light in the semiconductor substrate is larger than a size of the chip area; and
a driving mechanism configured to change a relative irradiation place of the laser light in the semiconductor substrate.

7. The laser irradiation apparatus according to claim 6, wherein semiconductor chips are formed in the chip areas.

8. The laser irradiation apparatus according to claim 6, wherein the laser light source generates laser light having a wavelength no shorter than 250 nm and no longer than 500 nm.

9. The laser irradiation apparatus according to claim 1, wherein
the laser light applied to the semiconductor substrate is pulsed laser light, and
an irradiation time for each place in the semiconductor substrate is 100 μsec or shorter.

10. The laser irradiation apparatus according to claim 1, wherein the semiconductor substrate is held in such a manner that the semiconductor substrate is not fixed at the irradiation place of the laser light.

11. The laser irradiation apparatus according to claim 1, wherein a distribution of intensity of the laser light is a top-flat distribution in an arbitrary one direction in the semiconductor substrate.

12. The laser irradiation apparatus according to claim 1, wherein a distribution of intensity of the laser light is a top-flat distribution in a direction in which the irradiation place of the laser light in the semiconductor substrate is changed and in a direction perpendicular to the direction in which the irradiation place is changed.

13. A laser irradiation method for activating a semiconductor layer of a semiconductor device, comprising the steps of:
(A1) generating laser light having a wavelength no shorter than 250 nm and no longer than 500 nm;
(A2) guiding the laser light to a semiconductor substrate by an optical system unit; and
(A3) changing a relative irradiation place of the laser light in the semiconductor substrate.

14. The laser irradiation method according to claim 13, wherein
a plurality of chip areas are provided in the semiconductor substrate, the plurality of chip areas being areas in each of which a semiconductor device is formed, and
the optical system unit shapes the laser light so that a longitudinal size of the laser light becomes larger than a size of the chip area in the semiconductor substrate.

15. The laser irradiation method according to claim 14, wherein
an adsorbing stage adsorbs and holds the semiconductor substrate, and
An irradiation place of the laser light in the semiconductor substrate is changed by driving the adsorbing stage.

16. The laser irradiation method according to claim 14, wherein
the semiconductor substrate is levitated by a levitation unit,
the semiconductor substrate, which is being levitated above the levitation unit, is conveyed in a first direction, and
the optical system unit disposed above the levitation unit is moved in a second direction different from the longitudinal direction in a plan view.

17. The laser irradiation method according to claim 13, wherein the laser light is scanned by an optical scanner provided in the optical system unit.

18. A laser irradiation method for applying laser light to a semiconductor substrate in which a plurality of chip areas are formed, comprising the steps of:
(B1) generating laser light;
(B2) guiding the laser light to the semiconductor substrate so that a longitudinal size of the laser light in the semiconductor substrate is larger than a size of the chip area; and
(B3) changing a relative irradiation place of the laser light in the semiconductor substrate.

19. The laser irradiation method according to claim 18, wherein semiconductor chips are formed in the chip areas.

20. The laser irradiation method according to claim 18, wherein a wavelength of the laser light is not shorter than 250 nm and not longer than 500 nm.

21. The laser irradiation method according to claim 13, wherein
the laser light applied to the semiconductor substrate is pulsed laser light, and
an irradiation time for each place in the semiconductor substrate is 100 μsec or shorter.

22. The laser irradiation method according to claim 13, wherein the semiconductor substrate is held in such a manner that the semiconductor substrate is not fixed at the irradiation place of the laser light.

23. The laser irradiation method according to claim 13, wherein a distribution of intensity of the laser light is a top-flat distribution in an arbitrary one direction in the semiconductor substrate.

24. The laser irradiation method according to claim 13, wherein a distribution of intensity of the laser light is a top-flat distribution in a direction in which the irradiation place of the laser light in the semiconductor substrate is changed and in a direction perpendicular to the direction in which the irradiation place is changed.

25. A method for manufacturing a semiconductor device, comprising (S1) an irradiation step of applying laser light to a semiconductor substrate in order to activate a semiconductor layer of-a power the semiconductor device, wherein
the (S1) irradiation step comprises the steps of:
(SA1) generating laser light having a wavelength no shorter than 250 nm and no longer than 500 nm;
(SA2) guiding the laser light to the semiconductor substrate by an optical system unit; and
(SA3) changing a relative irradiation place of the laser light in the semiconductor substrate.

26. The method for manufacturing a semiconductor device according to claim 25, wherein
a plurality of chip areas are provided in the semiconductor substrate, the plurality of chip areas being areas in each of which a semiconductor device is formed, and
the optical system unit shapes the laser light so that a longitudinal size of a spot shape of the laser light becomes larger than a size of the chip area in the semiconductor substrate.

27. The method for manufacturing a semiconductor device according to claim 26, wherein
an adsorbing stage adsorbs and holds the semiconductor substrate, and
An irradiation place of the laser light in the semiconductor substrate is changed by driving the adsorbing stage.

28. The method for manufacturing a semiconductor device according to claim 26, wherein
the semiconductor substrate is levitated by a levitation unit,
the semiconductor substrate, which is being levitated above the levitation unit, is conveyed in a first direction, and
the optical system unit disposed above the levitation unit is moved in a second direction different from the longitudinal direction in a plan view.

29. The method for manufacturing a semiconductor device according to claim 25, wherein the laser light is scanned by an optical scanner provided in the optical system unit.

30. A method for manufacturing a semiconductor device, comprising (T1) an irradiation step of applying laser light to a semiconductor substrate in which a plurality of chip areas are formed, wherein
the (T1) irradiation step comprises the steps of:
(TB1) generating laser light;
(TB2) guiding the laser light to the semiconductor substrate so that a longitudinal size of a spot shape of the laser light in the semiconductor substrate is larger than a size of the chip area; and
(TB3) changing a relative irradiation place of the laser light in the semiconductor substrate.

31. The method for manufacturing a semiconductor device according to claim 30, wherein semiconductor chips are formed in the chip areas.

32. The method for manufacturing a semiconductor device according to claim 30, wherein a wavelength of the laser light is not shorter than 250 nm and not longer than 500 nm.

33. The method for manufacturing a semiconductor device according to claim 25, wherein
the laser light applied to the semiconductor substrate is pulsed laser light, and
an irradiation time for each place in the semiconductor substrate is 100 μsec or shorter.

34. The method for manufacturing a semiconductor device according to claim 25, wherein the semiconductor substrate is held in such a manner that the semiconductor substrate is not fixed at the irradiation place of the laser light.

35. The method for manufacturing a semiconductor device according to claim 25, wherein a distribution of intensity of the laser light is a top-flat distribution in an arbitrary one direction in the semiconductor substrate.

36. The method for manufacturing a semiconductor device according to claim 25, wherein a distribution of intensity of the laser light is a top-flat distribution in a direction in which the irradiation place of the laser light in the semiconductor substrate is changed and in a direction perpendicular to the direction in which the irradiation place is changed.
